(19) United States
(12) Patent Application Publication
(10) Pub. No.: US 2008/0256416 A1
(43) Pub. Date: Oct. 16, 2008

(54) Apparatus and method for initializing memory

(75) Inventor: Hiromi Ozawa, Yamanashi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC COMPUTERTECHNO, LTD., Yamanashi (JP)

(21) Appl. No.: 12/078,938

(22) Filed: Apr. 8, 2008

(30) Foreign Application Priority Data
Apr. 11, 2007 (JP) 2007-103602

(51) Int. Cl. G06F 11/10; G06F 11/07; G11C 29/00

(52) U.S. Cl. 714/758; 714/763; 714/E11.032; 714/E11.021

(57) ABSTRACT

An apparatus includes a memory including a controller for initializing the memory, the controller storing a first data including a first code for correcting a first error of the first data, to the memory when initializing, and a memory controller controlling a data transmission to the memory, the memory controller being connected to the memory. The memory controller includes a code generation circuit storing a second data including a second code, to the memory after the initializing, the second code including an address parity for detecting an address causing a second error of the second data in said memory.

### INCORPORATION BY REFERENCE

This application is based upon and claims the benefit of priority from Japanese patent application No. 2007-103602, filed on Apr. 11, 2007, the disclosure of which is incorporated herein in its entirety by reference.

### BACKGROUND OF THE INVENTION

1. Field of the Invention

The present invention is directed to an apparatus including a memory, and more particularly to an apparatus for initializing the memory.

2. Description of Related Art

Systems, such as computers and servers, use a memory with large storage capacity in order to memorize and store various programs and data. A semiconductor memory, such as a dynamic random access memory (DRAM), as well as a magnetic storage device, such as a hard disk device (HDD), are used for such a memory. Usually, the memory is built into the system in advance as a dual inline memory module (DIMM), or added (expanded), as needed.

Conventionally, in order to guarantee data stored in the memory with an error correcting code (ECC), the memory needs to be tested and initialized with data being added to the ECC. Recently, a Chipkill-compatible ECC is used. By using the Chipkill technique, available data is kept on a memory so that the system can continuously operate even if a failure occurs in one of DRAM chips of the memory. In other words, in the Chipkill technique, ECC is distributed to a plurality of the DRAM chips of the memory.

On the contrary, in a non Chipkill-compatible ECC, the ECC is stored in a particular DRAM chip of the memory. Since the ECC is distributed to a plurality of the DRAM chips, even if a failure occurs in one of the DRAM chips, data is able to be restored by using the ECC stored in other DRAM chips which are not in failure. An example of the Chipkill-compatible ECC is an ECC using an S4EC-D4ED code. The S4EC-D4ED code ECC can be used in a DIMM (dual inline memory module) when the DRAM chip width is four-bits wide. Meanwhile, the width of data constituting the S4EC-D4ED code ECC is 16 bytes.

In addition, considering the availability of a system used in a mission-critical area, the test and initialization of a memory have to be performed by using the Chipkill-compatible ECC with an embedded address parity. The address parity may be used for detecting an address of memory which caused a fault. Usually, the test and initialization of the memory is performed by using an ECC generated from data of a certain value. Thus, the value of the Chipkill-compatible ECC becomes the same value for all of the addresses. Therefore, if an error is detected during system operation, then at which address is the data causing the error cannot be determined. However, when the test and initialization of the memory are performed with the Chipkill-compatible ECC with the address parity, if an error is detected during system operation, at which address is the data causing the error can be determined instantly. Thus, the availability of the system can be improved.

For the DIMM, a memory controller of the system is used to perform the test and initialization of a memory. This is because a function installed in the memory controller is not incorporated onto the DIMM. When the function installed in the memory controller is used to perform the test and initialization of the memory, an address at which the test and initialization are performed, ECC, the width and value of data or the like can be generated freely. Thus, it is possible to generate the Chipkill-compatible ECC with the address parity. Therefore, it is possible to perform the test and initialization of the memory by using the Chipkill-compatible ECC with the address parity. Accordingly, when the test and initialization of the memory is performed by using the memory controller, the availability of the system is improved.

However, since the test and the initialization are performed for each specified address over the entire memory of the system, it takes a long time for testing and initializing of the memory with the Chipkill-compatible ECC.

An FB-DIMM (Fully buffered DIMM) includes a memory controller. The memory controller of the FB-DIMM has a function with which, when ECC-associated data or data of a certain value is specified, the memory controller of the FB-DIMM uses the specified data to perform the test and initialization of the memory. With this function, the test and initialization of the memory can be performed in parallel per FB-DIMM unit. In other words, the time for testing and initializing by using the FB-DIMM is shortened compared with the non FB-DIMM memory.

Related arts regarding memory testing and ECC for the FB-DIMM are disclosed in various documents. A redundant module and a memory controller, which use an ECC/Chipkill circuit, is disclosed (see, e.g., Patent Document 1). Further, a memory system and a timing control method, which control a timing of an interface within a memory module using the FB-DIMM, is disclosed (see, e.g., Patent Document 2). In addition, a memory initialization method for writing initialization data including an ECC into a memory during startup is disclosed (see, e.g., Patent Document 3).

[Patent Document 1] Japanese Patent Laid-Open No. 2003-303139 (pp. 5 to 6, FIG. 1)

[Patent Document 2] Japanese Patent Laid-Open No. 2006-127515 (pp. 6 to 7, FIG. 1)

[Patent Document 3] Japanese Patent Laid-Open No. 61-34646 (pp. 2, FIG. 1)

FIG. 7 is a block diagram showing an example of a configuration of a system, which uses a memory control unit. The system 10 includes a system body 20 and a plurality (8 in this example) of FB-DIMM memories (hereinafter referred to as simply FB-DIMM) 30a to 30h, which are connected to the system body 20. A memory controller 21 for controlling these FB-DIMMs 30a to 30h is installed on the system body 20.

The FB-DIMM includes a controller (e.g., a local controller) which performs the test and the initialization of the respective FB-DIMM itself. By using the controller of the FB-DIMM, eight FB-DIMMs 30a to 30h can be concurrently (in parallel) tested and initialized. In contrast, when a memory controller (external controller) 21 of the system body 20 is used to perform the test and initialization of the FB-DIMMs 30a to 30h, the FB-DIMMs 30a to 30h are tested and initialized one by one (i.e., serially). Therefore, when the controller installed on the respective FB-DIMM is used to perform the test and initialization of the memory (FB-DIMM), the time spent on testing and initializing the memory can be substantially reduced as compared with a case where the memory controller 21 of the system body 20 is used.

### SUMMARY OF THE INVENTION

According to one exemplary aspect of the present invention, an apparatus, includes: a memory including a controller for initializing the memory, the controller storing a first data including a first code for correcting a first error of the first data to the memory when the initializing; and a memory controller controlling a data transmission to the memory, the memory controller being connected to the memory; and wherein the memory controller includes: a code generation circuit storing a second data including a second code to the memory after the initializing, the second code including an address parity for detecting an address being caused a second error of the second data in the memory.

According to another exemplary aspect of the present invention, an apparatus, includes: a unit for storing data which includes a controller for initializing the unit for storing data, the controller storing a first data including a first code for correcting a first error of the first data to the unit for storing data when the initializing; and a unit for controlling a data transmission to the unit for storing data, the unit for controlling being connected to the unit for storing data; and wherein the unit for controlling includes: a unit for storing a second data including a second code to the memory after the initializing, the second code including an address parity for detecting an address being caused a second error of the second data in the memory.

According to another exemplary aspect of the present invention, a method includes: initializing a memory by a controller installed on the memory, the controller storing a first data including a first code for correcting a first error of the first data to the memory when the initializing; and storing a second data including a second code to the memory after the initializing by a memory controller which is connected to the memory and controls a data transmission to the memory, the second code including an address parity for detecting an address causing a second error of the second data in the memory.

### BRIEF DESCRIPTION OF THE DRAWINGS

Other exemplary aspects and advantages of the invention will be made more apparent by the following detailed description and the accompanying drawings, wherein:

FIG. 1A shows a block diagram of a memory controller 201 according to an exemplary aspect of the present invention, the block diagram corresponding to a configuration for writing data to a memory;

FIG. 1B shows a block diagram of the memory controller 201 according to an exemplary aspect of the present invention, the block diagram corresponding to a configuration for reading data from the memory;

FIG. 2A shows an explanatory diagram of an exemplary operation of a first exemplary embodiment;

FIG. 2B shows an explanatory diagram of an exemplary operation of the first exemplary embodiment;

FIG. 3A shows a block diagram of a memory controller 401, the block diagram corresponding to a configuration for reading data from the memory;

FIG. 3B shows a block diagram of a memory controller 401, the block diagram corresponding to a configuration for writing data to a memory;

FIG. 4A shows an explanatory diagram of an exemplary operation of a second exemplary embodiment;

FIG. 4B shows an explanatory diagram of an exemplary operation of the second exemplary embodiment;

FIG. 5 shows a block diagram of a memory controller 601, the block diagram corresponding to a configuration for reading data from the memory;

FIG. 6 shows an explanatory diagram of an exemplary operation of a third exemplary embodiment; and

FIG. 7 shows a configuration diagram of a system to which an FB-DIMM is applied.

### DETAILED DESCRIPTION OF THE EXEMPLARY EMBODIMENTS

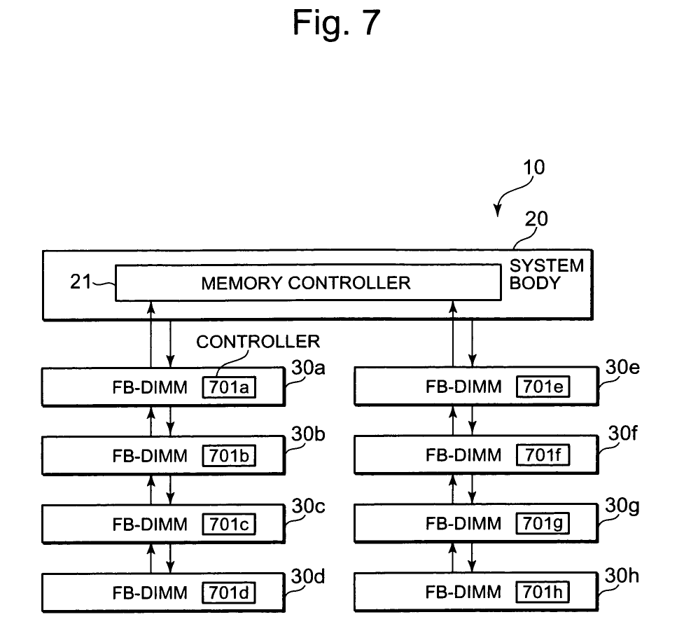

In the system 10 including the FB-DIMM, each of the FB-DIMMs 30a to 30h is tested and initialized substantially simultaneously by using respective controllers 701a to 701h (shown in FIG. 7) of the FB-DIMMs 30a to 30h. Therefore, even if the number of the FB-DIMMs 30 increases, the time spent on testing and initializing the memory is substantially the same as that prior to increasing the number of the FB-DIMMs 30.

If the memory capacity of each of the FB-DIMMs 30a to 30h is increased, the time spent on testing and initializing the memory increases even if the controllers 701a to 701h are used to perform the test and initialization of the memory. However, since each of the FB-DIMMs 30a to 30h is tested and initialized substantially simultaneously (e.g., in parallel), the time spent on testing and initializing increases only by the increased memory capacity of one FB-DIMM.

On the other hand, when the memory controller 21 installed on the system body 20 of the system 10 is used to perform the test and initialization of the memory, the time spent on testing and initializing the memory increases by “the increased memory capacity of one FB-DIMM multiplied by the number of the FB-DIMMs 30 incorporated”.

However, although, when each of the controllers 701a to 701h is used to perform the test and initialization of the memory, the time spent on testing and initializing the memory can be reduced, the test and initialization of the memory cannot be performed with the Chipkill-compatible ECC with the address parity. Therefore, the availability of the system 10 is significantly reduced as compared with a case where the memory controller 21 of the system 10 is used to perform the test and initialization of the memory.

Accordingly, in a system used in a mission-critical area, in order to improve the availability of the system 10, there is no choice but to use the memory controller 21 to perform the test and initialization of the memory.

An exemplary purpose of the present invention is to provide an apparatus and a method, capable of eliminating or reducing the time spent on testing and initializing memory while keeping the availability of the system.

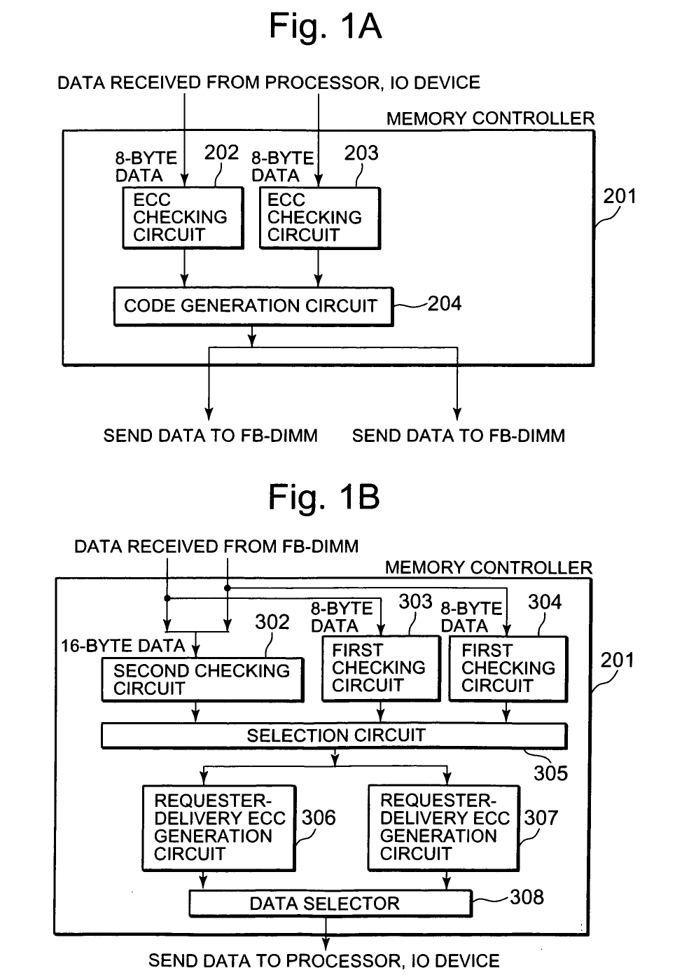

A first exemplary embodiment of the present invention will be described referring to FIGS. 1A and 1B. FIGS. 1A and 1B show an exemplary configuration of a memory controller 201 of the present invention. The memory controller 201 corresponds to the memory controller 21.

FIG. 1A is a block diagram showing a configuration of the memory controller 201 when data from a device (i.e., a processor or input/output (I/O) device) of the system is written into an FB-DIMM. Meanwhile, FIG. 1B is a block diagram showing the configuration of the memory controller 201 when data read out from the FB-DIMM is sent to the device (i.e., the processor or I/O device) of the system.

In FIG. 1A, the memory controller 201 includes ECC checking circuits 202 and 203, and a code generation circuit 204. The ECC checking circuits 202 and 203 check ECC based on the standard called “SEC-DED (Single bit Error Correcting-Double bit Error Detecting)”. The code generation circuit 204 generates ECC based on the standard called “S4EC-D4ED (Single 4-bit byte Error Correcting-Double 4-bit byte Error Detecting)”, for example. The S4EC-D4ED is an example of the Chipkill-compatible ECC. The present invention is not limited to the S4EC-D4ED. The ECC checking circuits 202 and 203 perform the ECC check and error correction of 8-byte data of 16-byte data received from the processor or I/O device. Further, the code generation circuit 204 generates, from the remaining 8-byte data sent from the ECC checking circuits 202 and 203, a Chipkill-compatible ECC with the address parity, which is to be sent to the FB-DIMM.

On the other hand, in FIG. 1B, the memory controller 201 includes first checking circuits 303 and 304, a second checking circuit 302, a selection circuit 305, requester-delivery ECC generation circuits 306 and 307, and a data selector 308.

The second checking circuit 302 and the first checking circuits 303 and 304 perform the ECC check and error correction of data received from the FB-DIMM (see reference numeral 30 in FIG. 7). The first checking circuits 303 and 304 check and correct the error based on the SEC-DED, for example. The second checking circuit 302 checks and corrects the error based on the S4EC-D4ED, for example.

Particularly, the second checking circuit 302 checks whether or not the ECC sent from the FB-DIMM 30 includes the Chipkill-compatible ECC with the address parity. More particularly, the second checking circuit 302 checks whether or not the data sent from the FB-DIMM 30 includes the address parity. The first checking circuits 303 to 304 check whether or not the ECC sent from the FB-DIMM 30 is an ECC generated at the time of the test and initialization of the memory.

Further, the selection circuit 305 determines whether the data sent from the second checking circuit 302 should be used, or whether the data sent from the first checking circuits 303 and 304 should be used, based on the result of the check of the second checking circuit 302 and the first checking circuits 303 and 304. The requester-delivery ECC generation circuits 306 and 307 generate, from the data sent from the selection circuit 305, an ECC to be sent to the device (i.e., the processor or I/O device). The requester-delivery ECC generation circuits 306 and 307 generate the ECC based on the SEC-DED, for example. The data selector 308 selects data to be sent to the device (i.e., the processor or I/O device).

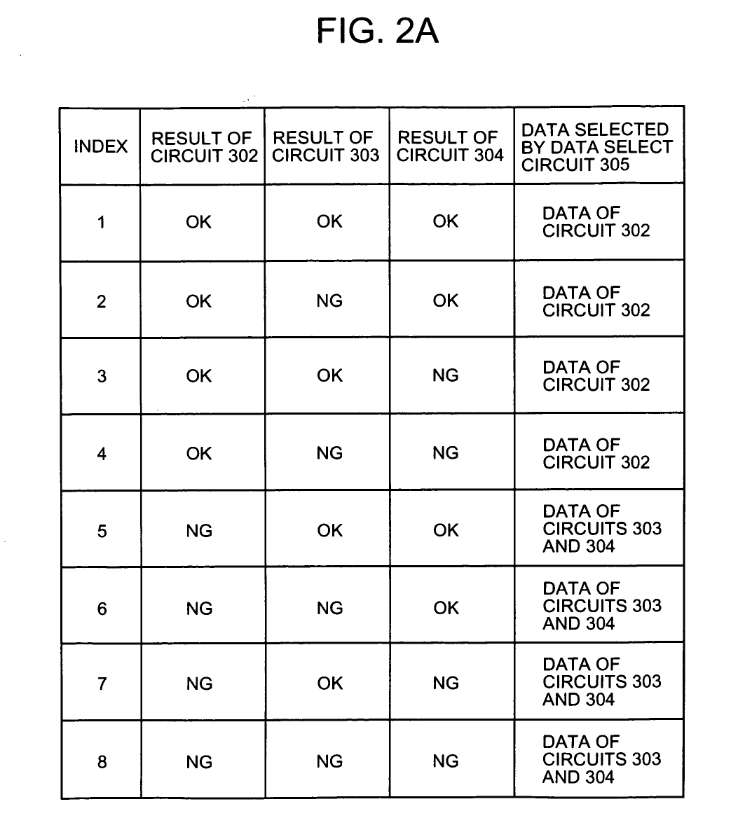

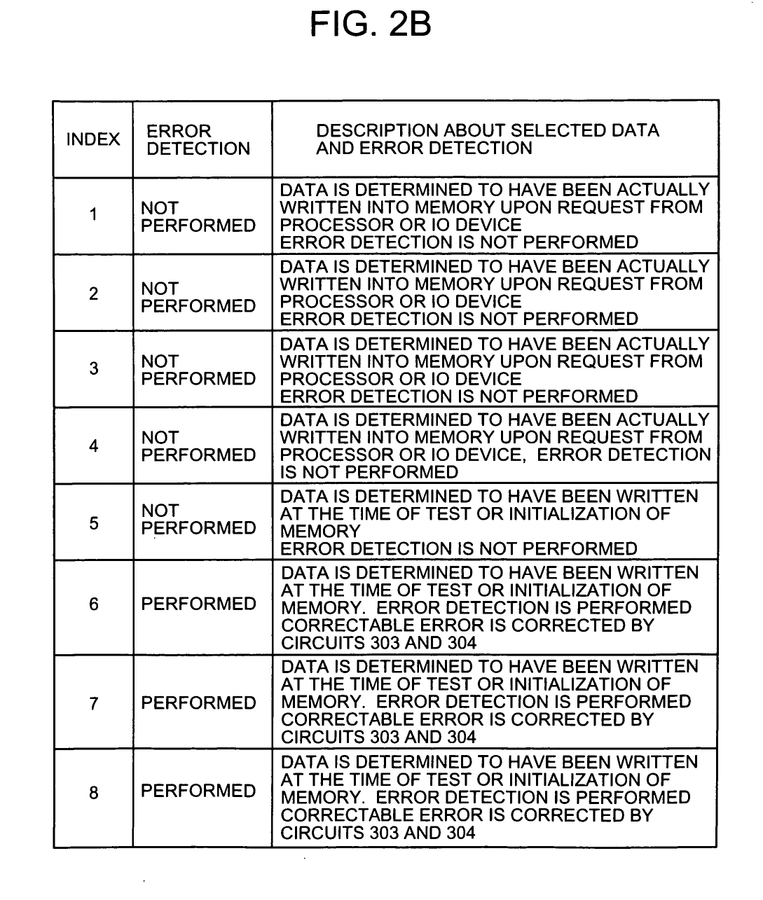

An exemplary operation of the first exemplary embodiment will be described referring to FIGS. 1 and 2. FIGS. 2A and 2B are an explanatory diagram of an exemplary operation of the selection circuit 305.

First, the test and initialization of the memory (i.e., FB-DIMM 30) will be described. The test and initialization of the memory is performed with ECC-associated data using the controller 701 of the FB-DIMM 30. The controller 701 of the FB-DIMM 30 is used to perform the test and initialization of the memory. Thus, for example, a function for performing the test and initialization of the memory does not need to be installed on the memory controller 21 (or external memory controller 201 of FIG. 1A) built into the system body 20 of the system 10.

Next, an operation to read data from the FB-DIMM 30 during a system operation will be described. The ECC and data sent from the FB-DIMM 30 are sent to the second checking circuit 302, and the first checking circuits 303 and 304 of FIG. 1B. The data and the ECC check results of the second checking circuit 302 and the first checking circuits 303 and 304 are sent to the selection circuit 305.

The selection circuit 305 determines which data should be selected, and whether or not an ECC error should be detected, based on a data error select method or a table shown in FIG. 2. Then, the ECC and data are sent from the requester-delivery ECC generation circuits 306 and 307, based on the determination result of the selection circuit 305. The ECC and data sent from the requester-delivery ECC generation circuits 306 and 307 are sent to the device (i.e., the processor or I/O device) through the data selector 308.

In FIGS. 2A and 2B, the results of the circuits 302 to 304, data selected by the selection circuit 305, whether or not error detection should be performed, and the description about the selected data and the error detection are shown.

In the first row (Index No. 1), the results of the circuits 302 to 304 are all “OK”, the selection circuit 305 selects the data of the circuit 302, and the circuits 303 and 304 does not detect the error based on the ECC. The selection circuit 305 determines that data sent from the circuit 302 is written into the memory upon request by the device (i.e., the processor or IO device), and the selection circuit 305 does not detect the error.

Meanwhile, in the last row (Index No. 8), the results of the circuits 302 to 304 are all “NG”, and the selection circuit 305 selects the data of the circuits 303 and 304. The selection circuit 305 detects the error detection, and determines that the data sent from the circuits 303 and 304 is written to the memory at the time of the test or initialization of the memory. A correctable error is corrected by the first checking circuits 303 and 304. Since other cases are as shown in FIGS. 2A and 2B, the description of them will be omitted. Each of the FB-DIMMs 30 is tested and initialized by the controller 701 simultaneously. This is a first stage of the test and initialization of the FB-DIMM 30.

Then, during the operation of the system after the test and initialization of the FB-DIMM 30, the code generation circuit 204 of the memory controller 201 generates the ECC with the address parity and writes the ECC with the address to the FB-DIMM 30. This is a second stage of the test and initialization of the FB-DIMM 30. In the first stage, the test and the initialization are done in a short time quickly and efficiently, because the test and the initialization are simultaneously performed on each of the FB-DIMMs 30 by the controller 701. Then, in the second stage, the test and initialization are done to improve the reliability of the system, because the ECC with the address parity is generated by the code generation circuit 204 after the first stage.

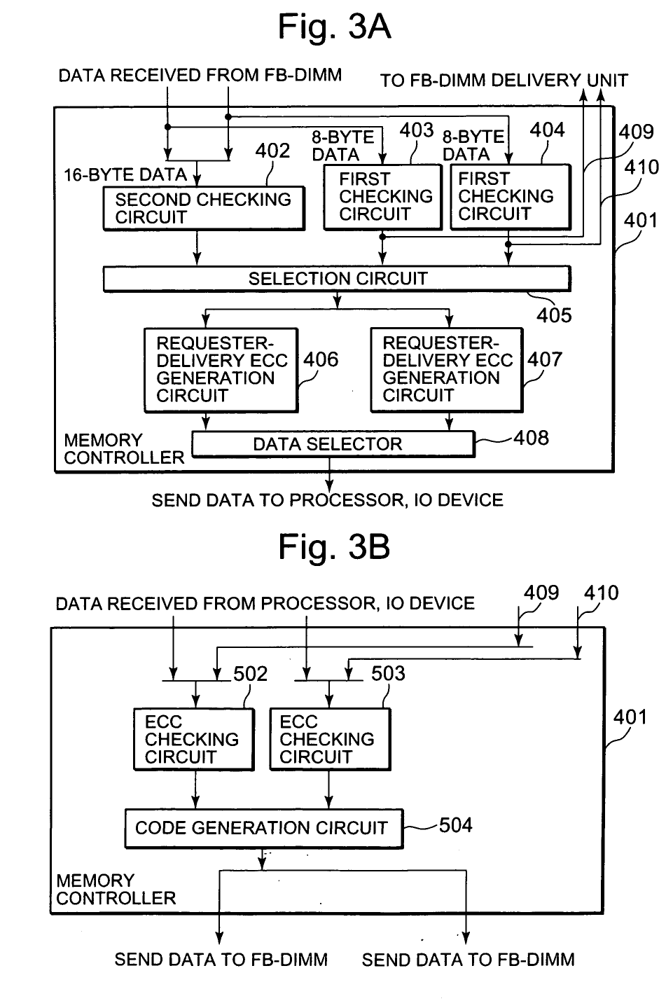

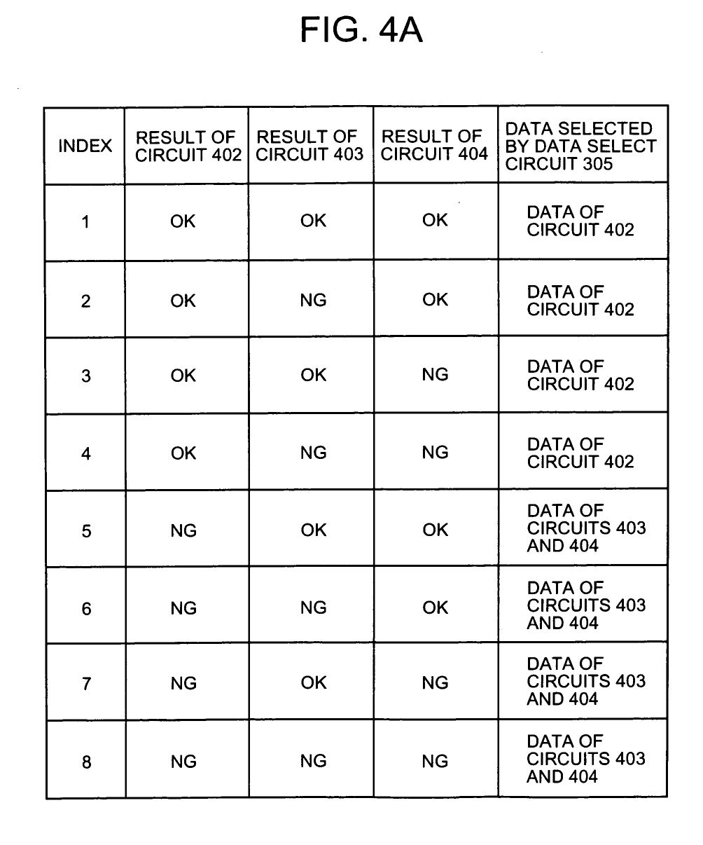

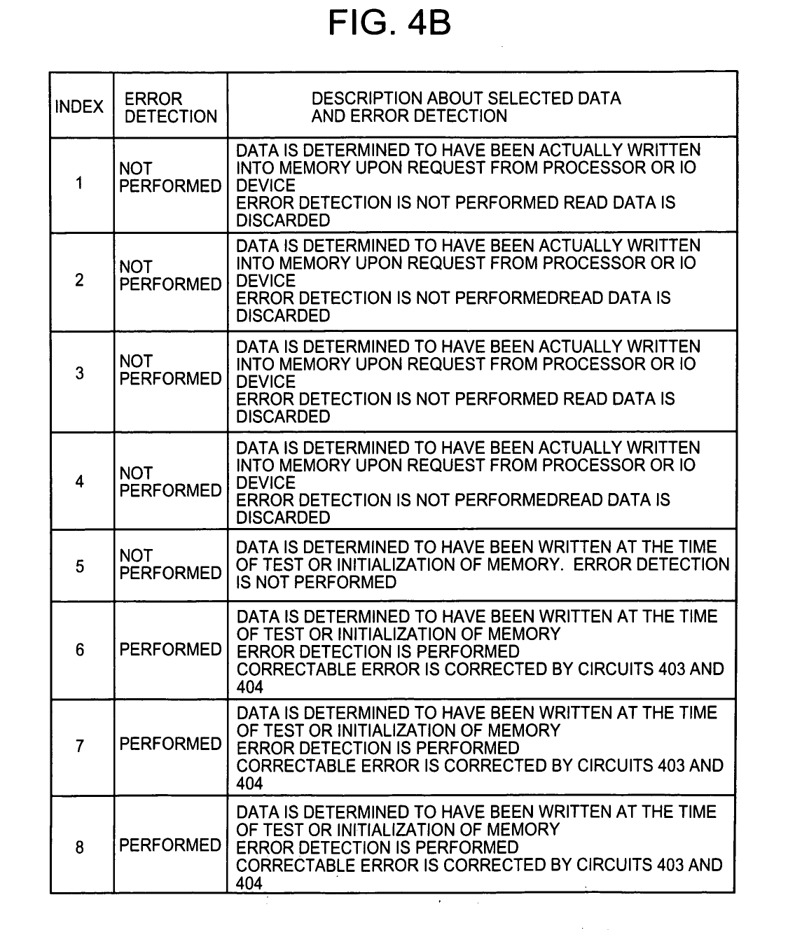

A second exemplary embodiment according to the present invention will be described referring to FIGS. 3, 4A and 4B. FIGS. 3, 4A and 4B are block diagrams showing an exemplary configuration of a memory controller 401 corresponding to FIGS. 1A and 1B. FIGS. 4A and 4B are the explanatory diagram of an exemplary operation of each circuit constituting the memory controller 401.

FIG. 3A is a block diagram showing the configuration of a memory controller 401 when data read out from the FB-DIMM is sent to the device (i.e., the processor or I/O device) of the system. Meanwhile, FIG. 3B is a block diagram showing the configuration of the memory controller 401 when data sent from a device (i.e., a processor or I/O device) of the system is written into the FB-DIMM.

Further, FIG. 4 is an explanatory diagram or a table showing the results of the circuits 402 to 404, data selected by a selection circuit 405, whether or not error detection should be performed, and the description about the selected data and the error detection.

In FIG. 3A, the memory controller 401 includes first checking circuits 403 to 404, a selection circuit 405, second checking circuit 402, requester-delivery ECC generation circuits 406 to 407, and a data selector 408. The first checking circuits 403 and 404 check ECC based on the SEC-DEC, for example. The second checking circuit 402 checks ECC based on the S4EC-D4ED, for example. The present invention is not limited to the SEC-DED and S4EC-D4ED. The second checking circuit 402 and the first checking circuits 403 and 404 perform the ECC check and error correction of data sent from the FB-DIMM 30.

Particularly, the second checking circuit 402 checks whether or not the ECC sent from the FB-DIMM 30 includes Chipkill-compatible ECC with the address parity. In other words, the second checking circuit checks whether or not the data sent from the FB-DIMM 30 includes the address parity. The first checking circuits 403 and 404 check whether or not the ECC sent from the FB-DIMM 30 is an ECC generated at the time of the test and initialization of the memory.

The selection circuit 405 determines whether the data sent from the second checking circuit 402 should be used, or whether the data sent from the first checking circuits 403 and 404 should be used, based on the result of the check of the second checking circuit 402 and the first checking circuits 403 and 404. The requester-delivery ECC generation circuits 406 and 407 generate, from the data sent from the selection circuit 405, an ECC to be delivered to the device (i.e., the processor or I/O device). The requester-delivery ECC generation circuits 406 and 407 generate the ECC based on the SEC-DED, for example. The data selector 408 selects data to be delivered to the device (i.e., the processor or I/O device).

The first checking circuits 403 and 404 send check data notification signals 409 and 410 for notifying the ECC and data to ECC checking circuits 502 and 503. The first checking circuits 403 and 404 may send the check data notification signals 409 and 410 to a code generation circuit 504.

In FIG. 3B, the memory controller 401 includes the ECC checking circuits 502 and 503, and the code generation circuit 504. The ECC checking circuits 502 and 503 perform the ECC check and error correction of data sent from the device (i.e., the processor or I/O device). The code generation circuit 504 generates, from the data sent from the ECC checking circuits 502 and 503, an ECC to be sent to the FB-DIMM 30.

An exemplary operation of the second exemplary embodiment will be described referring to FIGS. 3 and 4. The test and the initialization of the memory are performed with ECC-associated data using the controller 701 of the FB-DIMM 30, similarly to the first exemplary embodiment.

Data read from the FB-DIMM 30 by a “patrol function”, which is a function of the memory controller of the system, during system operation, will be described. The patrol function means a function of reading data from the memory periodically (patternwise from start to finish) until all of the data are read from the entire memory space. This is a function executed to detect/correct data destruction due to a “soft” error in advance, and prevent a non-correctable fatal error from being caused.

The ECC and data sent from the FB-DIMM 30 are sent to the second checking circuit 402 and the first checking circuits 403 and 404. The data and the ECC check results of the second checking circuit 402, and the first checking circuits 403 and 404 send the data and the ECC check results to the selection circuit 405. The selection circuit 405 determines which data should be selected, and whether or not an ECC error should be detected, based on a data error select method or a table shown in FIGS. 4A and 4B, and sends the selected data to the requester-delivery ECC generation circuits 406 and 407. The data selector 408 sends the ECC and data sent from the requester-delivery ECC generation circuits 406 and 407 to the device (i.e., the processor or I/O device).

As described above, in FIGS. 4A and 4B, the results of the circuits 402 to 404, data selected by the selection circuit 405, whether or not error detection should be performed, and the description about the selected data and the error detection are described.

When the selection circuit 405 determines that the data sent from the FB-DIMM 30 is written at the time of the test or initialization of the memory (Index No. 5, 6, 7 and 8 in FIGS. 4A and 4B), the ECC and data is sent to the ECC checking circuits 502 and 503 as the check data notification signals 409 and 410 from the first checking circuits 403 and 404.

When the selection circuit 405 does not detect the error (Index No. 5 in FIGS. 4A and 4B), the code generation circuit 504 generates the Chipkill-compatible ECC with the address parity, and sends the Chipkill-compatible ECC with the parity and data to the FB-DIMM 30.

Meanwhile, when the selection circuit 405 detects the error (Index No. 6, 7 and 8), the code generation circuit 504 generates the ECC of poisoned (fault or defective) data, and sends the ECC and data to the FB-DIMM 30. When the selection circuit 405 selects the data sent from the second checking circuit (Index No. 1, 2, 3 and 4), the data sent from the FB-DIMM 30 is discarded.

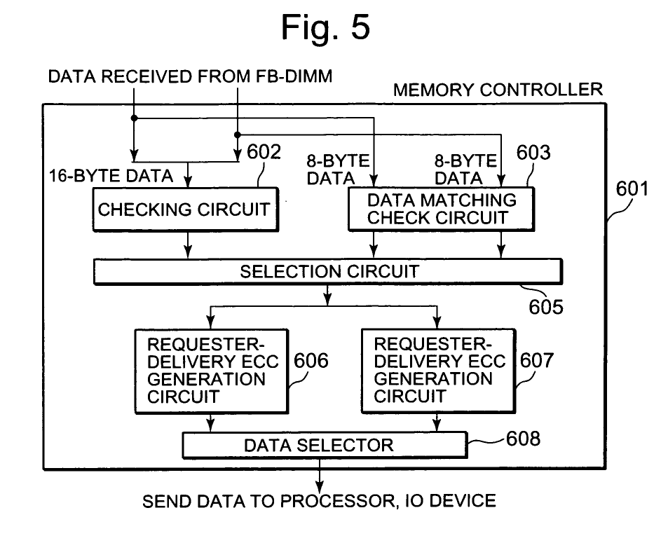

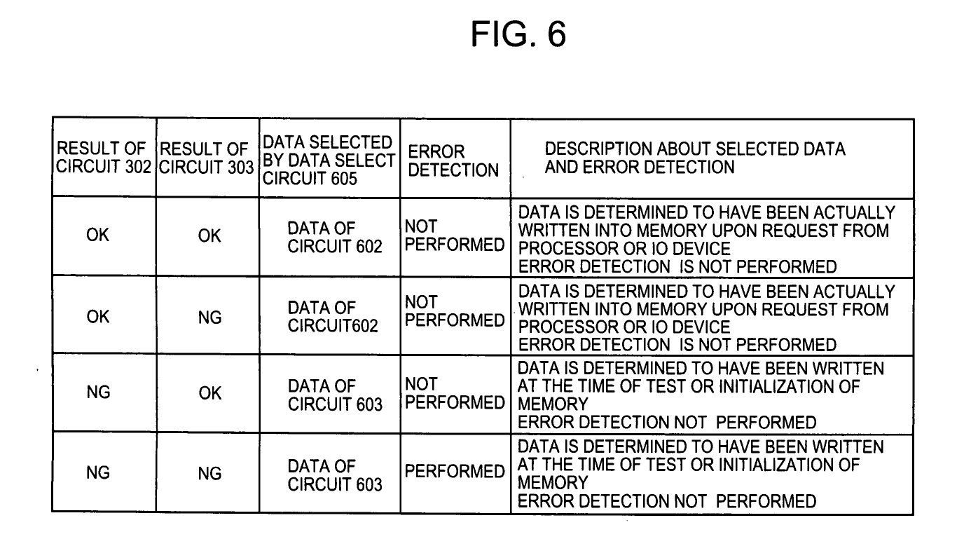

A third exemplary embodiment of the present invention will be described by referring to FIGS. 5 and 6. FIG. 5 is a block diagram of a memory controller 601 that sends data read from the FB-DIMM 30 to the device (i.e., the processor or I/O device). FIG. 6 is an explanatory diagram of an exemplary operation of the selection circuit 605 in FIG. 5.

In FIG. 5, the memory controller 601 includes a checking circuit 602, a data matching check circuit 603, a selection circuit 605, requester-delivery ECC generation circuits 606 and 607 and a data selector 608. The checking circuit 602 checks and corrects the error based on the S4EC-D4ED, for example. Here, the second checking circuit 602 performs the ECC check and error correction of data read from the FB-DIMM 30.

The data matching check circuit 603 performs matching check of the data read from the FB-DIMM 30. In other words, the data matching check circuit 603 determines whether each of the 8-byte data read from the FB-DIMM 30 match each other or not, for example.

The checking circuit 602 checks whether or not the ECC sent from the FB-DIMM 30 includes the Chipkill-compatible ECC with the address parity. In other words, the checking circuit 602 checks whether or not the data sent from the FB-DIMM 30 includes the address parity. The data matching check circuit 603 checks whether or not the ECC sent from the FB-DIMM 30 is an ECC generated at the time of the test and initialization of the memory.

The selection circuit 605 determines whether the data sent from the checking circuit 602 should be used, or the data sent from the data matching check circuit 603 should be used, based on the ECC check result of the checking circuit 602 and the data matching check result of the data matching check circuit 603. The requester-delivery ECC generation circuits 606 and 607 generate, from the data sent from the selection circuit 605, an ECC to be delivered to the device (i.e., the processor or I/O device). The requester-delivery ECC generation circuits 606 and 607 generate the ECC based on the SEC-DED, for example. The data selector 608 selects data to be delivered to the device (i.e., the processor or I/O device).

The test and initialization of the memory are performed by using the controller 701 of the FB-DIMM 30.

Data read from the FB-DIMM 30 during a system operation will be described. The ECC and data read from the FB-DIMM 30 are sent to the checking circuit 602 and the data matching check circuit 603 of FIG. 5. The data and the ECC check result of the checking circuit 602 and the data and the data matching check result of the data matching check circuit 603 are sent to the selection circuit 605.

The selection circuit 605 determines which data should be selected, and whether or not an ECC error should be detected, based on the data error select method or the table shown in FIG. 6, and sends them to the requester-delivery ECC generation circuits 606 and 607. The data selector 608 sends the data sent from the requester-delivery ECC generation circuits 606 and 607 to the device (i.e., the processor or I/O device).

Referring to FIG. 6, when the results of the circuits 602 and 603 in FIG. 5 are both “OK”, the selection circuit 605 selects the data of the circuit 602, and does not detect the error. Then, the selection circuit 605 determines that the data is written to the memory (first row in FIG. 6) upon the request from the device (i.e., the processor and I/O device).

Meanwhile, when the results of the circuits 602 and 603 are both NG, the selection circuit 605 selects the data of the circuit 603, then, the selection circuit 605 determines that the data is written at the time of the test or initialization of the memory, and detects the error (last row in FIG. 6). Since other cases are apparent from FIG. 6, their description will be omitted.

According to the present invention, many exemplary advantages are obtained. First, since the controller 701 of an FB-DIMM is used to perform the test and initialization of the memory, when memory capacity increases, the time spent on testing and initializing the memory can be substantially reduced.

In addition, despite using the controller 701 of the FB-DIMM to perform the test and initialization of the memory, the availability of the system can be maintained while reducing the time spent on testing and initializing the memory.

According to the present invention, the above configuration is included so that a circuit area and the power consumption can be reduced and the delay amount by the delay controller can be optimized.

It is noted that applicant's intent is to obtain all equivalents even if the claims are amended later during a prosecution.

While the invention has been described in terms of several exemplary embodiments, those skilled in the art will recognize that the invention can be practiced with modification within the spirit and scope of the appended claims.

What is claimed is:

1. An apparatus, comprising:
a memory including a controller that initializes said memory, said controller storing a first data, including a first code for correcting a first error of said first data, to said memory when initializing is performed; and
a memory controller that controls a data transmission to said memory, said memory controller being connected to said memory,
wherein said memory controller comprises:
a code generation circuit storing a second data including a second code, to said memory after said initializing, said second code including an address parity for detecting an address causing a second error of said second data in said memory.

2. The apparatus according to claim 1, wherein said memory comprises a plurality of ones of said memory, and
wherein each of said controllers initializes a corresponding memory substantially simultaneously.

3. The apparatus according to claim 1, wherein each of a plurality of ones of said memory serially connects with each other.

4. The apparatus according to claim 1, wherein said code generation circuit distributes said second code to a plurality of memory elements installed on said memory.

5. The apparatus according to claim 1, wherein said code generation circuit stores said second code to said memory when data read from said memory comprises said first data.

6. The apparatus according to claim 1, further comprising:
a first checking circuit that checks whether data read from said memory includes said first error, and that corrects said first error when said first error is included;
a second checking circuit that checks whether data read from said memory includes said second code; and
a selection circuit that selects data sent from either said first checking circuit or said second checking circuit based on a result of checking of said first checking circuit and said second checking circuit, and that sends selected data to a device that comprises a destination of said selected data.

7. The apparatus according to claim 6, wherein said selection circuit selects said data sent from said second checking circuit when said second checking circuit detects said second code.

8. The apparatus according to claim 7, wherein said selection circuit discards said data sent from said second checking circuit when said second checking circuit detects said second code.

9. The apparatus according to claim 6, wherein said selection circuit selects said data sent from said first checking circuit except when said second checking circuit detects said second code.

10. The apparatus according to claim 6, wherein said first checking circuit sends said first data to said code generation circuit when said first checking circuit detects said first data has a valid condition and said second checking circuit detects said second code is not included, and
wherein said code generation circuit generates said second data from said first data sent from said first checking circuit.

11. The apparatus according to claim 6, wherein said memory controller periodically checks said memory, and reads data from said memory,
wherein said first checking circuit sends said first data to said code generation circuit when said first checking circuit detects said first data has a valid condition and said second checking circuit detects said second code is not included, and
wherein said code generation circuit generates said second data from said first data sent from said first checking circuit.

12. An apparatus, comprising:
means for storing data which includes a controller for initializing said means for storing data, said controller storing a first data including a first code for correcting a first error of said first data, to said means for storing data when said initializing is performed; and
means for controlling a data transmission to said means for storing data, said means for controlling being connected to said means for storing data,
wherein said means for controlling comprises:
means for storing a second data including a second code, to said memory after said initializing, said second code including an address parity for detecting an address causing a second error of said second data in said memory.

13. A method, comprising:
initializing a memory by a controller installed on said memory, said controller storing a first data including a first code for correcting a first error of said first data, to said memory when said initializing is performed; and
storing a second data including a second code, to said memory after said initializing by a memory controller which is connected to said memory and controls a data transmission to said memory, said second code including an address parity for detecting an address causing a second error of said second data in said memory.

14. The method according to claim 13, wherein said memory comprises a plurality of ones of said memory, and
initializing a corresponding memory substantially simultaneously by each of said controllers.

15. The method according to claim 13, further comprising:
distributing said second code to a plurality of memory elements installed on said memory.

16. The method according to claim 13, further comprising:
storing said second code to said memory when data read from said memory comprises said first data.

17. The method according to claim 13, further comprising:
checking whether data read from said memory includes said first error by a first checking circuit;
correcting said first error when said first error is included;
checking whether data read from said memory includes said second code by a second checking circuit;
selecting data sent from either said first checking circuit or said second checking circuit based on a result of said checking; and
sending selected data to a device that comprises a destination of said selected data.

18. The method according to claim 17, further comprising:
selecting said data sent from said second checking circuit when said second code is detected by said second checking circuit.

19. The method according to claim 18, further comprising:
discarding said data sent from said second checking circuit when said second code is detected by said second checking circuit.

20. The method according to claim 17, further comprising:
selecting said data sent from said first checking circuit except when said second code is detected by said second checking circuit.

21. The method according to claim 17, further comprising:
generating said second data including said second code when said first checking circuit detects said first data has a valid condition and said second checking circuit detects said second code is not included.

22. The apparatus according to claim 17, further comprising:
checking said memory periodically by said memory controller;
reading data from said memory; and
generating said second data including said second code when said first checking circuit detects said first data has a valid condition and said second checking circuit detects said second code is not included.
